(19) United States
(12) Patent Application Publication
(10) Pub. No.: US 2025/0379563 A1
(43) Pub. Date: Dec. 11, 2025

(54) SYSTEM AND METHOD OF MODULATING TRANSITION FREQUENCY OF SUPERCONDUCTING QUANTUM BIT

(71) Applicants: UNIVERSITY OF SCIENCE AND TECHNOLOGY OF CHINA, Hefei (CN); Hefei National Laboratory, Hefei (CN)

(72) Inventors: Lei Jiang, Hefei (CN); Yu Xu, Hefei (CN); Shaowei Li, Hefei (CN); Chenyin Sun, Hefei (CN); Tianzuo Sun, Hefei (CN); Tao Jiang, Hefei (CN); Jinjin Li, Hefei (CN); Chengzhi Peng, Hefei (CN); Xiaobo Zhu, Hefei (CN); Jianwei Pan, Hefei (CN)

(21) Appl. No.: 18/736,102

(22) Filed: Jun. 6, 2024

(30) Foreign Application Priority Data
Jun. 9, 2023 (CN) 202310680483.3

(51) Int. Cl. H03K 5/00; G06N 10/60

(52) U.S. Cl. CPC H03K 5/00006; G06N 10/60

(57) ABSTRACT

The present disclosure provides a system of modulating a transition frequency of a superconducting quantum bit. The system includes: at least one bias line for a radio frequency superconducting quantum interference device, configured to transmit an electrical signal for adjusting a state of the radio frequency superconducting quantum interference device; at least one radio frequency superconducting quantum interference device located on a chip and placed near the superconducting quantum bit, where a hysteresis parameter of the radio frequency superconducting quantum interference device is greater than 1; and at least one superconducting quantum bit, where the transition frequency of the superconducting quantum bit is modulated by applying an external magnetic flux. The present disclosure further provides a method of modulating a transition frequency of a superconducting quantum bit

### CROSS-REFERENCE TO RELATED APPLICATIONS

This application is claims priority to Chinese Application No. 2023106804833 filed on Jun. 9, 2023, which is incorporated herein by reference in its entirety.

### TECHNICAL FIELD

The present disclosure relates to a field of superconducting quantum computing, and in particular to a system and a method of modulating a transition frequency of a superconducting quantum bit.

### BACKGROUND

Quantum computing is expected to solve problems that cannot be solved by current classical computing in many fields, such as multi-body physics simulation, encryption algorithm design, chemical reaction simulation, and prediction of biological microscopic behavior. Superconducting quantum computers based on superconductor materials are important platforms for achieving quantum computing. An important technical means for implementing quantum logic gates, quantum state measurement, quantum algorithms and general quantum computing in superconducting quantum computers is to regulate a transition frequency of a superconducting quantum bit. The related art involves placing an on-chip microwave transmission line near the superconducting quantum bit. Such a transmission line is integrated with the quantum bit on the same chip. An electrical signal (including current signal and voltage signal) in the transmission line may be converted into a magnetic flux signal through a mutual inductance between the transmission line and the quantum bit. The magnetic flux signal may be input into the quantum bit to change the transition frequency of the quantum bit. However, the related art has problems such as high power consumption and poor scalability.

### SUMMARY

The present disclosure provides a system and a method of modulating a transition frequency of a superconducting quantum bit.

According to a first aspect of the present disclosure, a system of modulating a transition frequency of a superconducting quantum bit is provided, including: at least one bias line for a radio frequency superconducting quantum interference device, configured to transmit an electrical signal for adjusting a state of the radio frequency superconducting quantum interference device; at least one radio frequency superconducting quantum interference device located on a chip and placed near the superconducting quantum bit, where a hysteresis parameter of the radio frequency superconducting quantum interference device is greater than 1; and at least one superconducting quantum bit, where the transition frequency of the superconducting quantum bit is modulated by applying an external magnetic flux; where the system of modulating the transition frequency of the superconducting quantum bit is operable in an extremely low temperature environment of an order of 10 mK of a dilution refrigerator.

According to embodiments of the present disclosure, the bias line for the radio frequency superconducting quantum interference device is coupled with the radio frequency superconducting quantum interference device through a mutual inductance; the bias line for the radio frequency superconducting quantum interference device is located on the chip and is connected to a signal source in a room temperature environment through a coaxial cable in the dilution refrigerator; the bias line for the radio frequency superconducting quantum interference device is configured to convert the electrical signal into a magnetic flux signal through the mutual inductance between the bias line and the radio frequency superconducting quantum interference device and input the magnetic flux signal into the radio frequency superconducting quantum interference device; a bandwidth of the bias line of the radio frequency superconducting quantum interference device covers at least a frequency range from a frequency of DC signal to 5 GHz; and the state of the radio frequency superconducting quantum interference device is modulated by an electrical signal with a specific direction and a specific amplitude inputted to the bias line for the radio frequency superconducting quantum interference device.

According to embodiments of the present disclosure, the radio frequency superconducting quantum interference device is a closed loop including a superconducting ring made of a superconducting material and at least one Josephson junction connected with the superconducting ring end to end.

According to embodiments of the present disclosure, a mutual inductance coupling is formed between the superconducting quantum bit and the radio frequency superconducting quantum interference device.

According to embodiments of the present disclosure, the bias line for the radio frequency superconducting quantum interference device is configured to convert an input electrical signal into a magnetic flux signal through a mutual inductance and input the magnetic flux signal into the radio frequency superconducting quantum interference device, and the input electrical signal is a current signal or a voltage signal.

According to embodiments of the present disclosure, a superconducting ring current in the radio frequency superconducting quantum interference device is converted into a magnetic flux signal through a mutual inductance and input into the superconducting quantum bit to modulate the transition frequency of the superconducting quantum bit.

According to embodiments of the present disclosure, a change relationship between a total magnetic flux of the radio frequency superconducting quantum interference device and the external magnetic flux exhibits a behavior of a hysteresis curve, an external magnetic flux signal in form of pulse is applied to modulate the state of the radio frequency superconducting quantum interference device, and the state of the radio frequency superconducting quantum interference device includes a direction and a magnitude of a superconducting ring current in the radio frequency superconducting quantum interference device.

According to embodiments of the present disclosure, the state of the radio frequency superconducting quantum interference device is allowed to be maintained in a changed state for a long time after being changed by a pulse signal input; and the direction and the magnitude of the superconducting ring current in the radio frequency superconducting quantum interference device is allowed to be kept constant for a long time.

According to a second aspect of the present disclosure, a method of modulating a transition frequency of a superconducting quantum bit is provided, which is applied to a system of modulating a transition frequency of a superconducting quantum bit, where the method includes: inputting the electrical signal in form of single pulse from a signal source into the bias line for the radio frequency superconducting quantum interference device, where the electrical signal in form of single pulse is a current signal or a voltage signal; converting the electrical signal in form of single pulse into a magnetic flux signal in form of pulse through a mutual inductance between the bias line for the radio frequency superconducting quantum interference device and the radio frequency superconducting quantum interference device; inputting the magnetic flux signal in form of pulse into the radio frequency superconducting quantum interference device to change a state of the radio frequency superconducting quantum interference device so that the radio frequency superconducting quantum interference device in a changed state modulates the transition frequency of the superconducting quantum bit through a mutual inductance between the radio frequency superconducting quantum interference device and the superconducting quantum bit, where a hysteresis parameter of the radio frequency superconducting quantum interference device is greater than 1.

According to embodiments of the present disclosure, the inputting the magnetic flux signal in form of pulse into the radio frequency superconducting quantum interference device to change a state of the radio frequency superconducting quantum interference device so that the radio frequency superconducting quantum interference device in a changed state modulates the transition frequency of the superconducting quantum bit through a mutual inductance between the radio frequency superconducting quantum interference device and the superconducting quantum bit includes: converting, by using the bias line, the electrical signal in form of single pulse with a specific direction and a specific amplitude into an external magnetic flux signal in form of single pulse through a mutual inductance between the bias line and the radio frequency superconducting quantum interference device according to a hysteresis loop relationship between the external magnetic flux and the total magnetic flux of the radio frequency superconducting quantum interference device, and inputting the external magnetic flux signal in form of single pulse into the radio frequency superconducting quantum interference device to change the state of the radio frequency superconducting quantum interference device, where the state of the radio frequency superconducting quantum interference device includes a direction and a magnitude of a superconducting ring current in the radio frequency superconducting quantum interference device; and modulating, by using the superconducting ring current, the transition frequency of the superconducting quantum bit through a mutual inductance between the radio frequency superconducting quantum interference device and the superconducting quantum bit; where the direction of the superconducting ring current in the radio frequency superconducting quantum interference device is related to a direction of the external magnetic flux signal in form of single pulse inputted the radio frequency superconducting quantum interference device; and where the magnitude of the superconducting ring current in the radio frequency superconducting quantum interference device is related to an amplitude of the external magnetic flux signal in form of single pulse inputted the radio frequency superconducting quantum interference device.

### BRIEF DESCRIPTION OF THE DRAWINGS

The above contents and other objectives, features and advantages of the present disclosure will become more apparent through the following description of the embodiments of the present disclosure with reference to the accompanying drawings. In the accompanying drawings:

FIG. 1 shows a schematic structural diagram of a system of modulating a transition frequency of a superconducting quantum bit according to embodiments of the present disclosure;

FIG. 2 shows a flowchart of a method of modulating a transition frequency of a superconducting quantum bit according to embodiments of the present disclosure; and

FIG. 3 shows a schematic diagram of a hysteresis loop relationship between a total magnetic flux ¢ and an external magnetic flux de of a radio frequency superconducting quantum interference device according to embodiments of the present disclosure.

### DETAILED DESCRIPTION OF EMBODIMENTS

In order to make objectives, technical solutions and advantages of the present disclosure more clearly understood, the present disclosure will be further described in detail below in conjunction with specific embodiments and with reference to the accompanying drawings.

It should be noted that the figures provided in the embodiments of the present disclosure are just used to illustrate the basic concept of the present disclosure in a schematic manner. The figures only show components related to the present disclosure and are not drawn according to the number, shape and size of components in actual implementation. The type, quantity and proportion of each component may be changed arbitrarily in actual implementation, and a layout of components may be more complicated.

In a superconducting quantum computer in the related art, an on-chip microwave transmission line is placed near a superconducting quantum bit, and the transmission line is integrated with the quantum bit on the same chip. An electrical signal in the transmission line may be converted into a magnetic flux signal through a mutual inductance between the transmission line and the quantum bit, and the magnetic flux signal may be input into the quantum bit to change a transition frequency of the quantum bit.

However, the solutions in the related art have the following disadvantages. First, the electrical signal needs to be continuously input from a signal source at a room temperature to a superconducting quantum processor in a low-temperature environment of a refrigerator. The continuously input electrical signal may generate heat when passing through various attenuators on a low-temperature coaxial cable in the refrigerator. Long-term heating may make it difficult to maintain the low-temperature environment in the refrigerator, and a thermal radiation generated by the heating may also affect a performance of the quantum processor. Secondly, with an increase in the number of quantum bits, a demand for the number of coaxial transmission lines in the refrigerator may also increase exponentially, which requires a larger physical space inside the refrigerator and puts higher requirements on cooling power of the refrigerator, and thus limits a scalability of the superconducting quantum processor.

Therefore, it is important and urgent to achieve a low-power scalable solution for modulating a transition frequency of a quantum bit on a future superconducting processor with thousands of quantum bits.

In view of the above, the present disclosure provides a system and a method of modulating a transition frequency of a superconducting quantum bit to achieve the solution of modulating the transition frequency of the superconducting quantum bit, so as to solve the problems of high energy consumption and non-scalability in the related art.

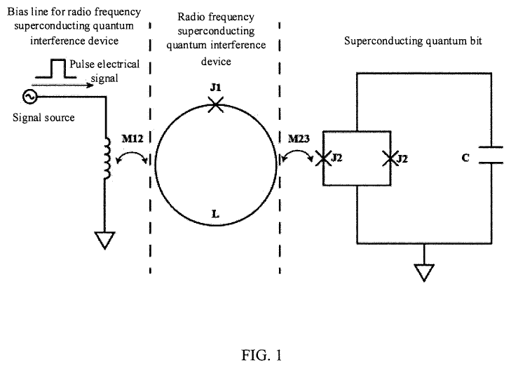

FIG. 1 shows a schematic structural diagram of a system of modulating a transition frequency of a superconducting quantum bit according to embodiments of the present disclosure.

As shown in FIG. 1, the system of modulating the transition frequency of the superconducting quantum bit includes: at least one bias line for a radio frequency superconducting quantum interference device, which is used to transmit an electrical signal for adjusting a state of the radio frequency superconducting quantum interference device; at least one radio frequency superconducting quantum interference device located on a chip and placed near the superconducting quantum bit, where a hysteresis parameter of the radio frequency superconducting quantum interference device is greater than 1; at least one superconducting quantum bit, where the transition frequency of the superconducting quantum bit is modulated by applying an external magnetic flux; where the system used to modulate the transition frequency of the superconducting quantum bit operates in an extremely low temperature environment of an order of 10 mK in a dilution refrigerator.

The hysteresis parameter of the above-mentioned radio frequency superconducting quantum interference device is expressed by Equation (1).

$${β}_{e} = 2 π \frac{{I}_{c} L}{{Φ}_{0}} \qquad ( 1 )$$

where I_{c} represents a critical Josephson current in the radio frequency superconducting quantum interference device, L represents a self-inductance of the radio frequency superconducting quantum interference device, and Φ₀ represents a magnetic flux quantum. Φ₀ is expressed by Equation (2).

$${Φ}_{0} = 2.07 \times {10}^{- 15} V \cdot s \qquad ( 2 )$$

It should be clear to those skilled in the art that a transmon qubit is taken as an example in FIG. 1, but the above-mentioned system provided by the present disclosure is not limited to the transmon qubit.

The above-mentioned radio frequency superconducting quantum interference device (RF-SQUID) is based on a superconducting Josephson effect and a magnetic flux quantization, and is generally used to measure a weak magnetic signal.

Optionally, the radio frequency superconducting quantum interference device is placed in a range of 0.1 microns to 20 microns of the superconducting quantum bit.

As shown in FIG. 1, M12 represents a mutual inductance between the bias line for the radio frequency superconducting quantum interference device and the radio frequency superconducting quantum interference device, M23 represents a mutual inductance between the radio frequency superconducting quantum interference device and the superconducting quantum bit (that is, superconducting quantum bit circuit), C represents a capacitance, J1 represents a Josephson junction of the radio frequency superconducting quantum interference device, J2 represents a Josephson junction in the superconducting quantum bit, and L represents a self-inductance coil of the radio frequency superconducting quantum interference device.

The system provided by the present disclosure may be implemented to modulate a transition frequency of a superconducting quantum bit based on a radio frequency superconducting quantum interference device. The electrical signal used in the system may modulate the transition frequency of the superconducting quantum bit for a long time using a limited number of pulse signal inputs with an extremely low energy consumption. Moreover, the radio frequency superconducting quantum interference device is integrated on the chip for easy expansion, which may help provide a scalable transition frequency modulation solution for a future superconducting quantum computer with thousands of superconducting quantum bits.

According to embodiments of the present disclosure, the bias line for the radio frequency superconducting quantum interference device is coupled with the radio frequency superconducting quantum interference device through a mutual inductance. The bias line for the radio frequency superconducting quantum interference device is located on the chip, and is connected to a signal source in a room temperature environment through a coaxial cable in a dilution refrigerator. The bias line for the radio frequency superconducting quantum interference device may convert an electrical signal into a magnetic flux signal through the mutual inductance between the bias line and the radio frequency superconducting quantum interference device, and input the magnetic flux signal into the radio frequency superconducting quantum interference device. A bandwidth of the bias line for the radio frequency superconducting quantum interference device may cover at least a frequency range from a frequency of DC signal to 5 GHz. The state of the radio frequency superconducting quantum interference device may be modulated by an electrical signal with a specific direction and a specific amplitude inputted to the bias line for the radio frequency superconducting quantum interference device.

According to embodiments of the present disclosure, the radio frequency superconducting quantum interference device is a closed loop including a superconducting ring made of a superconducting material and at least one Josephson junction connected with the superconducting ring end to end.

According to embodiments of the present disclosure, a mutual inductance coupling is formed between the superconducting quantum bit and the radio frequency superconducting quantum interference device.

According to embodiments of the present disclosure, the bias line for the radio frequency superconducting quantum interference device may convert an input electrical signal into a magnetic flux signal through a mutual inductance and input the magnetic flux signal into the radio frequency superconducting quantum interference device. The input electrical signal is a current signal or a voltage signal.

According to embodiments of the present disclosure, a superconducting ring current in the radio frequency superconducting quantum interference device may be converted into a magnetic flux signal through a mutual inductance and input into the superconducting quantum bit, so as to modulate the transition frequency of the superconducting quantum bit.

According to embodiments of the present disclosure, a relationship between a total magnetic flux of the radio frequency superconducting quantum interference device and the external magnetic flux exhibits a behavior of a hysteresis curve, and an external magnetic flux signal in form of pulse may be applied to modulate the state of the radio frequency superconducting quantum interference device. The state of the radio frequency superconducting quantum interference device includes a direction and a magnitude of the superconducting ring current in the radio frequency superconducting quantum interference device.

According to embodiments of the present disclosure, the state of the radio frequency superconducting quantum interference device may be maintained in a changed state for a long time after being changed by a pulse signal input; and the direction and the magnitude of the superconducting ring current in the radio frequency superconducting quantum interference device may be kept constant for a long time.

The state of the radio frequency superconducting quantum interference device may be maintained for a very long time after being changed by a pulse signal input. For example, for a radio frequency superconducting quantum interference device with a critical Josephson current of 100 microamperes at a stable ambient temperature of 20 mK, the state of the radio frequency superconducting quantum interference device may be maintained for 1014 seconds, i.e., three million years.

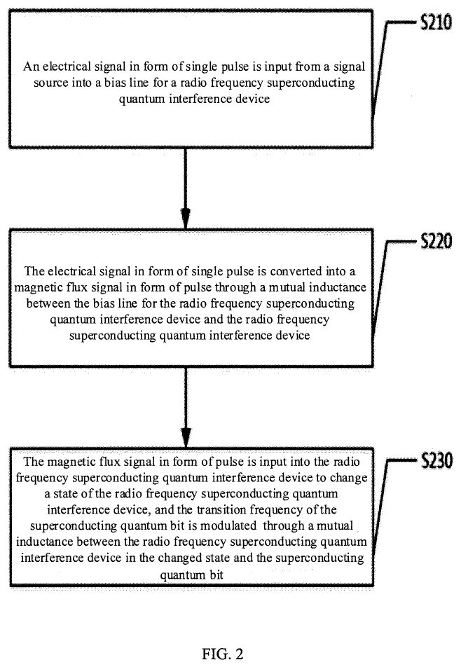

FIG. 2 shows a flowchart of a method of modulating a transition frequency of a superconducting quantum bit according to embodiments of the present disclosure.

As shown in FIG. 2, the method of modulating the transition frequency of the superconducting quantum bit may be applied to a system of modulating a transition frequency of a superconducting quantum bit, and may include operation S210 to operation S230.

In operation S210, an electrical signal in form of single pulse is input from a signal source into a bias line for a radio frequency superconducting quantum interference device, where the single pulse electrical signal may be a current signal or a voltage signal.

In operation S220, the electrical signal in form of single pulse is converted into a magnetic flux signal in form of pulse through a mutual inductance between the bias line for the radio frequency superconducting quantum interference device and the radio frequency superconducting quantum interference device.

In operation S230, the magnetic flux signal in form of pulse is input into the radio frequency superconducting quantum interference device to change a state of the radio frequency superconducting quantum interference device so that the radio frequency superconducting quantum interference device in a changed state modulates the transition frequency of the superconducting quantum bit through a mutual inductance between the radio frequency superconducting quantum interference device and the superconducting quantum bit, where a hysteresis parameter of the radio frequency superconducting quantum interference device is greater than 1.

According to embodiments of the present disclosure, inputting the magnetic flux signal in form of pulse into the radio frequency superconducting quantum interference device to change a state of the radio frequency superconducting quantum interference device so that the radio frequency superconducting quantum interference device in a changed state modulates the transition frequency of the superconducting quantum bit through a mutual inductance between the radio frequency superconducting quantum interference device and the superconducting quantum bit may include: converting, by using the bias line, the electrical signal in form of single pulse with a specific direction and a specific amplitude into an external magnetic flux signal in form of single pulse through a mutual inductance between the bias line and the radio frequency superconducting quantum interference device according to a hysteresis loop relationship between the external magnetic flux and the total magnetic flux of the radio frequency superconducting quantum interference device, and inputting the external magnetic flux signal in form of single pulse into the radio frequency superconducting quantum interference device to change the state of the radio frequency superconducting quantum interference device, where the state of the radio frequency superconducting quantum interference device includes a direction and a magnitude of a superconducting ring current in the radio frequency superconducting quantum interference device; and modulating, by using the superconducting ring current, the transition frequency of the superconducting quantum bit through a mutual inductance between the radio frequency superconducting quantum interference device and the superconducting quantum bit; where the direction of the superconducting ring current in the radio frequency superconducting quantum interference device is related to a direction of the external magnetic flux signal in form of single pulse inputted the radio frequency superconducting quantum interference device; and the magnitude of the superconducting ring current in the radio frequency superconducting quantum interference device is related to an amplitude of the single pulse external magnetic flux signal in form of single pulse inputted the radio frequency superconducting quantum interference device.

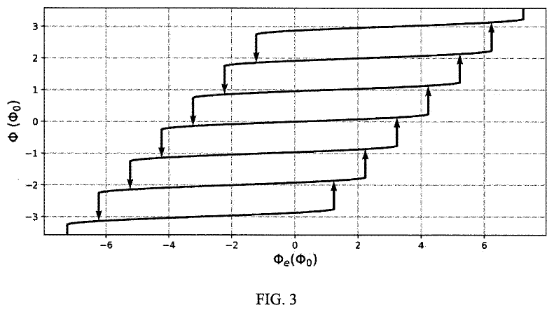

In order to better illustrate the advantages of the above-mentioned method, the above-mentioned method will be further described in detail in the present disclosure with reference to FIG. 3 and specific embodiments.

FIG. 3 shows a schematic diagram of a hysteresis loop relationship between a total magnetic flux ¢ and an external magnetic flux de of a radio frequency superconducting quantum interference device according to embodiments of the present disclosure.

Specifically, in such embodiments, an electrical signal in form of single pulse (which may be a current signal or a voltage signal) is input from a signal source into a bias line for an RF-SQUID, and is converted into a magnetic flux signal in form of pulse through a mutual inductance M12 between the bias line for the RF-SQUID and the RF-SQUID and input into the RF-SQUID. Since the hysteresis parameter of the RF-SQUID is greater than 1, a relationship between a total magnetic flux and an external magnetic flux of the RF-SQUID may exhibit a hysteresis loop relationship, as shown in FIG. 3. An amplitude of the pulse electrical signal applied by the signal source is adjusted. When an amplitude of the converted magnetic flux signal reaches a value at a critical point (a magnitude of the external magnetic flux corresponding to a starting position of each arrow in FIG. 3) of the external magnetic flux in the hysteresis loop relationship between the total magnetic flux and the external magnetic flux of the RF-SQUID, the relationship between the total magnetic flux and the external magnetic flux of the RF-SQUID may jump from a relationship indicated by a previous curve to a relationship indicated by a next curve corresponding to the critical point. A specific jumping direction depends on whether a changing direction of the external magnetic flux is positive or negative, as shown by upward and downward arrows in FIG. 3. Here, the state of the RF-SQUID is described by a parameter of total magnetic flux, and a state change behavior of the RF-SQUID after a jump may follow the relationship described by the curve after the jump. At this time, if the external magnetic flux gradually decreases to 0, the total magnetic flux of the RF-SQUID may also gradually decrease along a curve path after the jump. Finally, the state of the RF-SQUID stays at the intercept position of the y-axis of the curve and may remain stable in the state corresponding to that position for a long time. In the state corresponding to the intercept position, the total magnetic flux of the RF-SQUID is non-zero. In other words, a superconducting ring current with a specific direction and a specific magnitude exists in the RF-SQUID. Such superconducting ring current may be converted into a magnetic flux signal through a mutual inductance M23 between the RF-SQUID and the superconducting quantum bit, and input into a transmon qubit (the transmon qubit is taken as an example here, but the above-mentioned method provided by the present disclosure is not limited to the transmon qubit) to modulate a transition frequency of the transmon qubit. Since the RF-SQUID may be maintained at the state corresponding to the intercept position of the curve for a very long time, the superconducting current in the RF-SQUID is very stable, which ensures that the modulation of the transition frequency of the superconducting quantum bit is also very stable. Similarly, the state of the RF-SQUID may also be reversely modulated according to the hysteresis loop relationship between the total magnetic flux and the external magnetic flux of the RF-SQUID, so that the RF-SQUID is modulated from a superconducting ring current state of non-zero to a state of zero or even a superconducting ring current state with a reverse current direction. In this way, the transition frequency of the superconducting quantum bit may be modulated by inputting forward and reverse magnetic fluxes from the perspective of the quantum bit.

In summary, with the method of modulating the transition frequency of the superconducting quantum bit based on the RF-SQUID according to the present disclosure, the transition frequency of the superconducting quantum bit may be modulated to be stable for a long time by inputting just an electrical signal in form of pulse. Compared with the current solution of on-chip microwave transmission line which requires inputting a continuous electrical signal, inputting an electrical signal in form of pulse may significantly reduce an energy consumption of an entire modulation process, which makes it possible to simultaneously modulate the transition frequency of all superconducting quantum bits in a superconducting quantum processor with thousands of quantum bits in the future.

The above specific embodiments further describe the objectives, technical solutions and beneficial effects of the present disclosure in detail. It should be understood that the above are just specific embodiments of the present disclosure and are not intended to limit the present disclosure. Any modifications, equivalent substitutions, improvements, etc. made within the spirit and principles of the present disclosure should be contained in the protection scope of the present disclosure.

What is claimed is:

1. A system of modulating a transition frequency of a superconducting quantum bit, comprising:
at least one bias line for a radio frequency superconducting quantum interference device, configured to transmit an electrical signal for adjusting a state of the radio frequency superconducting quantum interference device;
at least one radio frequency superconducting quantum interference device located on a chip and placed near the superconducting quantum bit, wherein a hysteresis parameter of the radio frequency superconducting quantum interference device is greater than 1; and
at least one superconducting quantum bit, wherein the transition frequency of the superconducting quantum bit is modulated by applying an external magnetic flux;
wherein the system of modulating the transition frequency of the superconducting quantum bit is operable in an extremely low temperature environment of an order of 10 mK of a dilution refrigerator.

2. The system according to claim 1, wherein the bias line for the radio frequency superconducting quantum interference device is coupled with the radio frequency superconducting quantum interference device through a mutual inductance;
wherein the bias line for the radio frequency superconducting quantum interference device is located on the chip and is connected to a signal source in a room temperature environment through a coaxial cable in the dilution refrigerator;
wherein the bias line for the radio frequency superconducting quantum interference device is configured to convert the electrical signal into a magnetic flux signal through the mutual inductance between the bias line and the radio frequency superconducting quantum interference device and input the magnetic flux signal into the radio frequency superconducting quantum interference device;
wherein a bandwidth of the bias line of the radio frequency superconducting quantum interference device covers at least a frequency range from a frequency of DC signal to 5 GHz; and
wherein the state of the radio frequency superconducting quantum interference device is modulated by an electrical signal with a specific direction and a specific amplitude inputted to the bias line for the radio frequency superconducting quantum interference device.

3. The system according to claim 1, wherein the radio frequency superconducting quantum interference device is a closed loop comprising a superconducting ring made of a superconducting material and at least one Josephson junction connected with the superconducting ring end to end.

4. The system according to claim 1, wherein a mutual inductance coupling is formed between the superconducting quantum bit and the radio frequency superconducting quantum interference device.

5. The system according to claim 1, wherein the bias line for the radio frequency superconducting quantum interference device is configured to convert an input electrical signal into a magnetic flux signal through a mutual inductance and input the magnetic flux signal into the radio frequency superconducting quantum interference device, and the input electrical signal is a current signal or a voltage signal.

6. The system according to claim 1, wherein a superconducting ring current in the radio frequency superconducting quantum interference device is converted into a magnetic flux signal through a mutual inductance and input into the superconducting quantum bit to modulate the transition frequency of the superconducting quantum bit.

7. The system according to claim 1, wherein a relationship between a total magnetic flux of the radio frequency superconducting quantum interference device and the external magnetic flux exhibits a behavior of a hysteresis curve, an external magnetic flux signal in form of pulse is applied to modulate the state of the radio frequency superconducting quantum interference device, and the state of the radio frequency superconducting quantum interference device comprises a direction and a magnitude of a superconducting ring current in the radio frequency superconducting quantum interference device.

8. The system according to claim 1, wherein the state of the radio frequency superconducting quantum interference device is allowed to be maintained in a changed state for a long time after being changed by a pulse signal input; and
wherein the direction and the magnitude of the superconducting ring current in the radio frequency superconducting quantum interference device is allowed to be kept constant for a long time.

9. A method of modulating a transition frequency of a superconducting quantum bit, applied to a system of modulating a transition frequency of a superconducting quantum bit, the system comprising: at least one bias line for a radio frequency superconducting quantum interference device, configured to transmit an electrical signal for adjusting a state of the radio frequency superconducting quantum interference device; at least one radio frequency superconducting quantum interference device located on a chip and placed near the superconducting quantum bit, wherein a hysteresis parameter of the radio frequency superconducting quantum interference device is greater than 1; and at least one superconducting quantum bit, wherein the transition frequency of the superconducting quantum bit is modulated by applying an external magnetic flux; wherein the system of modulating the transition frequency of the superconducting quantum bit is operable in an extremely low temperature environment of an order of 10 mK of a dilution refrigerator;
wherein the method comprises:
inputting the electrical signal in form of single pulse from a signal source into the bias line for the radio frequency superconducting quantum interference device, wherein the electrical signal in form of single pulse is a current signal or a voltage signal;
converting the electrical signal in form of single pulse into a magnetic flux signal in form of pulse through a mutual inductance between the bias line for the radio frequency superconducting quantum interference device and the radio frequency superconducting quantum interference device;
inputting the magnetic flux signal in form of pulse into the radio frequency superconducting quantum interference device to change a state of the radio frequency superconducting quantum interference device, so that the radio frequency superconducting quantum interference device in a changed state modulates the transition frequency of the superconducting quantum bit through a mutual inductance between the radio frequency superconducting quantum interference device and the superconducting quantum bit, wherein a hysteresis parameter of the radio frequency superconducting quantum interference device is greater than 1.

10. The method according to claim 9, wherein the inputting the magnetic flux signal in form of pulse into the radio frequency superconducting quantum interference device to change a state of the radio frequency superconducting quantum interference device so that the radio frequency superconducting quantum interference device in a changed state modulates the transition frequency of the superconducting quantum bit through a mutual inductance between the radio frequency superconducting quantum interference device and the superconducting quantum bit comprises:
converting, by using the bias line, the electrical signal in form of single pulse with a specific direction and a specific amplitude into an external magnetic flux signal in form of single pulse through a mutual inductance between the bias line and the radio frequency superconducting quantum interference device according to a hysteresis loop relationship between the external magnetic flux and the total magnetic flux of the radio frequency superconducting quantum interference device, and inputting the external magnetic flux signal in form of single pulse into the radio frequency superconducting quantum interference device to change the state of the radio frequency superconducting quantum interference device, wherein the state of the radio frequency superconducting quantum interference device comprises a direction and a magnitude of a superconducting ring current in the radio frequency superconducting quantum interference device; and
modulating, by using the superconducting ring current, the transition frequency of the superconducting quantum bit through a mutual inductance between the radio frequency superconducting quantum interference device and the superconducting quantum bit;
wherein the direction of the superconducting ring current in the radio frequency superconducting quantum interference device is related to a direction of the external magnetic flux signal in form of single pulse inputted the radio frequency superconducting quantum interference device; and
wherein the magnitude of the superconducting ring current in the radio frequency superconducting quantum interference device is related to an amplitude of the external magnetic flux signal in form of single pulse inputted the radio frequency superconducting quantum interference device.
